(19) United States
(12) Patent Application Publication
(10) Pub. No.: US 2010/0126556 A1
(43) Pub. Date: May 27, 2010

(54) PHOTOVOLTAIC CONCENTRATOR WITH AUXILIARY CELLS COLLECTING DIFFUSE RADIATION

(75) Inventors: Pablo Benitez, Madrid (ES); Juan Carlos Miñano, Madrid (ES); Roberto Alvarez, Glendale, CA (US)

Correspondence Address: DRINKER BIDDLE & REATH;ATTN: INTELLECTUAL PROPERTY GROUP, ONE LOGAN SQUARE, SUITE 2000, PHILADELPHIA, PA, 19103-6996, US

(73) Assignee: Light Prescriptions Innovators, LLC

(21) Appl. No.: 12/622,664

(22) Filed: Nov. 20, 2009

Related U.S. Application Data
(60) Provisional application No. 61/199,947, filed on Nov. 21, 2008.
(60) Provisional application No. 61/214,548, filed on Apr. 24, 2009.

(51) Int. Cl. H01L 31/052

(52) U.S. Cl. 136/246

(57) ABSTRACT

High-concentration photovoltaic concentrators can utilize much more expensive high-efficiency cells because they need so much less of them, but much of the solar resource is left ungathered thereby. The main cell is at the focal spot of the concentrator. Low-cost secondary solar cells are now added to the concentrator, surrounding the main cell. Diffuse skylight and misdirected normal rays irradiate these secondary cells, adding to output. Also, the power plant can have output on cloudy days, unlike conventional concentrators. As cell costs fall relative to other costs, this system becomes economically superior to both flat-plate and concentrator systems.

### CROSS-REFERENCE TO RELATED APPLICATIONS

This application claims benefit of U.S. Provisional Patent Application No. 61/199,947 for a “Photovoltaic concentrator with auxiliary cells collecting diffuse radiation,” filed Nov. 21, 2008 by Benítez et al., which is incorporated herein by reference in its entirety.

Reference is also made to U.S. Provisional Patent Application No. 61/214,548 titled “Four-Junction Two-Terminal Photovoltaic Device,” filed 24 Apr. 2009 by Benítez et al., which is incorporated herein by reference in its entirety.

### TECHNICAL FIELD

The present invention relates generally to photovoltaic solar energy.

### BACKGROUND

Photovoltaic solar electricity is produced by means of a converter that is capable of transforming sunlight into electrical power. Different types of solar cells have different conversion efficiencies. Currently (late 2008) commercially available thin film solar cells have efficiencies of about 10%, whereas commercially available crystalline or polycrystalline flat-panel silicon solar cells have somewhat higher efficiency, 15% to 20%. The “Sunpower 230 solar panel” (from the Sunpower Corporation), is currently the most efficient commercial 1-sun silicon module. It is based on back-contact cell technology and produces 185 W/m² at the industry Standard Test Conditions (STC). The STC comprises a solar spectrum defined by ASTM G173-03 at airmass 1.5, normal incidence, a global irradiance of 1000 W/m², and a cell temperature of 25° C. Monocrystalline silicon solar modules from the Spanish company Isofoton produce 120 W/m² at STC, and thin-film amorphous silicon modules from Japanese company Kaneka produce 63 W/m² under the same conditions.

Usually, the power units at STC are referred to as peak-Watts, or Wₚ (and Wₚ/m² when referring to the power density). In real-world operation (variable temperature, changing spectrum, module-to-module mismatch current losses, among other non-Standard factors) different technologies behave very differently from those under STC. The combination of all the real-world factors (which also includes wiring losses, DC to AC conversion efficiency and tracking losses) are usually included in the ratio of the annual electricity generated to the nominal STC peak power of the module, measured by kWh/kWₚ, or hours per year at peak power. When divided by 8760 hours (365×24 hours) per year, the percentage ratio is called the capacity factor, effectively measuring the average actual power output as a percentage of kWₚ. The inverse of the capacity factor, multiplied by the nominal per-peak-Watt capital cost of the solar energy, gives the capital cost per average Watt, which can more meaningfully be compared with the cost of a baseload system. Usually, this rating is for output AC as a turn-key system, and is particular to the site and system design (since it depends on the actual irradiation, temperatures, shading of the modules, and tracking performance).

A promising technology is III-V materials for solar cells, which already have been proven to achieve efficiencies in commercial cells in the region of 35-40%. They are known as triple junction cells because of their three junctions in a tandem-series monolithic configuration, but their high efficiency comes at high cost. Today's bare cells cost in the range of $100-200/m² for thin film, $300-500/m² for flat-panel silicon, and $100,000-150,000/m² for III-V. The only way the expensive cells can compete is for an optical concentrator to reduce the area of semiconductor devoted to a given amount of power. With enough concentration comes cost-competitiveness.

From optics fundamentals, when high concentration is used, the solid angle that can be collected is necessarily reduced. The geometrical concentration C_{g} is the ratio of concentrator entry aperture area to solar cell area, as distinct from the necessarily lesser number of suns of average flux on the cell. Typical geometrical concentration ratios C_{g} for III-V solar cells are in the range of 200 to 1,000, known as high concentration photovoltaics (HCPV). The maximum half-angle of acceptance that can be 100% collected is α=sin⁻¹(n/√C_{g}), where n is the refractive index of the encapsulant material surrounding the solar cell. As a consequence, high concentration photovoltaic systems (HCPV) must follow the sun with a two-axis tracking system, and they collect only that solar radiation coming directly from the sun's disk (which, in the absence of clouds, is an approximately uniform-radiance disk with a cone half-angle of 0.265 degrees, which varies ±3% during the year).

Around the disc is a circumsolar component due to small-angle scattering, which can vary widely in radiance and angular extent, depending on atmospheric conditions. Pyrheliometers usually measure the sum of both components, everything within ±2.5°. Hereinafter pyrheliometer data are referred to by their customary acronym DNI for direct normal irradiance (in W/m²) or irradiation (in kWh/(m²·yr)). The ratio of the DNI to GNI (global normal irradiation, which includes the DNI along with a diffuse component from the whole sky) received by the same two-axis tracking surface varies depending on the location, and due to ground reflectance. Efficient use of high concentration requires clear sunny locations where the direct to global irradiation ratio is high, typically 70-80%, but 85-90% in deserts and mountains vs. 50-65% in hazy locations. Both one-sun flat plates and tracking concentrators are normalized to 1 kW/m² of input, but these don't describe the same conditions. A given amount of global irradiance GNI will generally mean a lesser amount of DNI. Thus STC for flat-plates vs. concentrators are different, in order that actual input be the same.

HCPV market penetration directly competes with flat panel silicon modules mounted on two-axis trackers. The drawbacks of the HCPV modules with respect to flat panels on two axis trackers are: (1) HCPV collects only the DNI (in some systems, those with a very small acceptance angle, not all of the circumsolar radiation is collected), (2) additional costs must be included: the concentrator optics, heat sinks (to de-concentrate the power not converted into electricity), (3) the optical efficiency is never 100% (usually in the 70-90% range), and (4) typically a higher accuracy is required when manufacturing, assembling, installing and maintaining the HCPV system, so as not to tax the limited acceptance angle of the concentrator.

To be competitive, these drawbacks must be compensated for by higher cell efficiency. Spectrolab triple junction III-V cells, which are 36% efficient at 500 suns and 25° C., in a 500 sun concentrator with 75% optical efficiency (i.e., with required geometrical concentration C_{g}=500/0.75=667), will produce 270 W/m² of entry area, if illuminated with a DNI of 1 kW/m² at the entry aperture. Although this is an 85%-ile level for most sunny locations, it is used for easy division. At present, few commercial CPV systems perform close to 270 Wₚ/m² (the German company Concentrix is one of them, but has a C_{g} of only 282×, while others show values closer to 200 Wₚ/m² or less). Such lower efficiency is usually due to mismatched photocurrents between concentrator units, resulting in intra-module current losses in cell-to-cell series connections (necessitated by low cell voltage needing to be raised).

The following table summarizes the comparison between these different technologies, showing the nominal annual DC electrical energy density produced in kWh/(m²·year). HCPV output will be 75% higher than that of the medium-efficiency silicon, but only 14% higher than the high-efficiency silicon modules. However, due to the higher accuracy needed for most present day HCPV systems (in assembly, installation, etc.) these gains may be difficult to attain cost-effectively.

| | III-V HCPV | High | Medium | Low efficiency |
|---|---|---|---|---|
| | (36% efficient | efficiency | efficiency | thin-film |
| | cell with 75% | silicon | silicon | silicon |
| | efficient optics) | (SunPower) | (Isofoton) | (Kaneka) |
| Cell irradiance | 500 | 1 | 1 | 1 |
| (kW/m²) | | | | |
| Electrical power | 270 | 185 | 120 | 63 |
| density at STC | | | | |
| (Wₚ/m²) | | | | |
| Annual solar | 2012 (DNI) | 2580 (GNI) | 2580 (GNI) | 2580 (GNI) |
| irradiation (at | | | | |
| Seville) | | | | |
| (kWh/(m² · year)) | | | | |
| Nominal annual DC | 2012*0.270 = | 2580*0.185 = | 2580*0.12 = | 2580*0.063 = |
| electrical energy | 543 | 477 | 310 | 163 |
| density | (175%) | (154%) | (100%) | (52%) |
| (kWh/(m² · year)) | | | | |

### SUMMARY OF THE INVENTION

One aspect of the present invention relates generally to a photovoltaic system that can produce a high annual electrical energy density (kWh/(m²·year)), with the potential to do so at a lower cost than state of the art PV and CPV technologies. The invention comprises a combination of two types of photovoltaic solar cells in a single module. A lower-cost cell type receives the diffuse solar radiation while a higher-efficiency cell type receives the direct normal (DNI) solar radiation. Optionally the system can also receive albedo solar radiation (i.e. reflected from the ground) both from front and back of the module (typically this is achieved by putting reflective pebbles or paint around the base of the system, possibly adding as much as 5% to system output). The diffuse sunlight may be cost-effectively collected by a concentrator.

### BRIEF DESCRIPTION OF THE DRAWINGS

The above and other aspects, features and advantages of the present invention will be apparent from the following more particular description of certain embodiments, presented in conjunction with the following drawings wherein:

FIG. 1 shows a PV concentrator with auxiliary cells.

FIG. 2 shows a generic block diagram of a solar photovoltaic system.

FIG. 3 is a cost comparison diagram of tracking one-sun to concentrators.

FIG. 4 is a cost comparison of concentrators to assisted concentrators.

FIG. 5 is a cost comparison of all three of the types compared in FIGS. 3 and 4.

FIG. 6 shows a PV concentrator with a Fresnel primary lens in which the auxiliary cell is used as a heat spreader.

### DETAILED DESCRIPTION OF THE DRAWINGS

The embodiment of a system shown in the drawings relates generally to photovoltaic systems with high annual electrical energy density (kWh/(m²·year)). It makes use of the fact that the angular distribution of the solar radiation is very non-uniform, being mainly concentrated around the sun's disk (beam and circumsolar irradiance), from a small angular region of the sky, but with significant irradiance coming from the entire sky, and in some cases the ground (especially if the ground has high reflectivity, e.g., snow, or deliberately provided white or light-colored ground). The direct normal irradiation (DNI) is concentrated upon a small and expensive high-efficiency cell, while the usually less intense diffuse radiation is collected by a large but low-cost lower-efficiency cell. If the latter has low enough cost, the extra energy it generates will have a capital cost no more than that collected by the expensive cell. On cloudy days a tracking system can aim straight up and generate three-fourths the electricity that a pure flat-plate array of low-cost cells would, but with much lower marginal non-cell costs (wiring, structures, land, etc.) than the flat-plate array. Because the extra low-cost lower-efficiency cells do not significantly increase HCPV operating or maintenance costs, the marginal cost is merely their purchase and installation cost, since everything else has been paid for as part of HCPV capital cost.

In general, two types of photovoltaic solar cells are combined in a module, such that one of the cell types receives the solar radiation from a first angular region of the sky R_{H} of solid-angle Ω_{H}, while the other cell type receives the sun from a second angular region of the sky R_{L} of solid-angle Ω_{L}. The average sun radiance in the first region R_{H} is higher than in the second region R_{L}. (Optionally, there could be third and fourth regions collecting ground reflections.) The cells receiving radiation from angular region R_{H} will have a cost C_{H} and a conversion efficiency η_{H}, while the cells receiving radiation from angular region R_{L} will have a cost C_{L} and a conversion efficiency η_{L}; so that the following inequalities will preferably apply:

Ω_{H}≦Ω_{L} C_{H}≧C_{L} η_{H}≧η_{L}

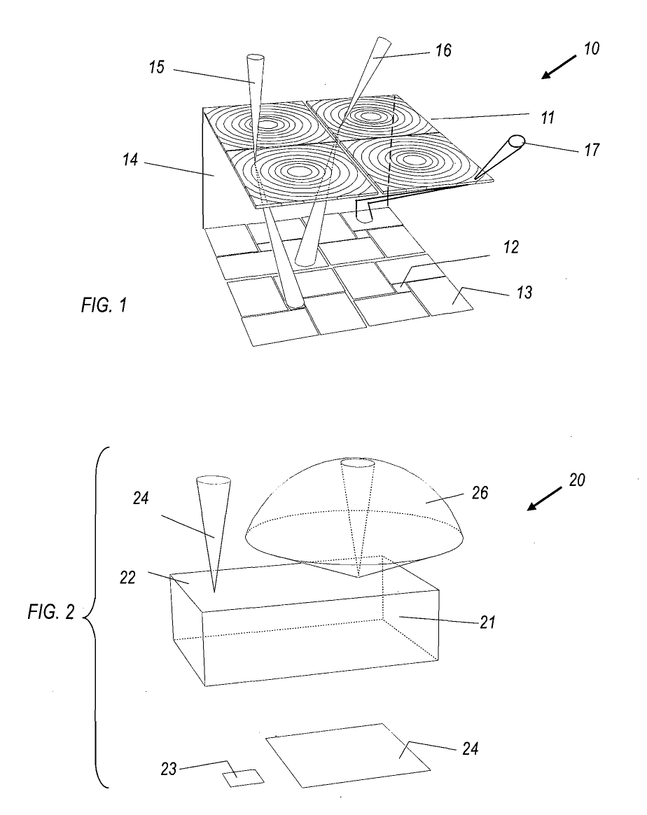

There are multiple ways of implementing a system complying with those constraints, as one skilled in the art would be able to determine once the principles of this invention are clearly understood. FIG. 1 shows a Fresnel-lens based HCPV system indicated generally by the reference numeral 10. Fresnel lenses 11 are designed to collect the DNI from the region of the sky R_{H} (represented by an incoming pencil of rays) 15 and concentrate the DNI on CPV photovoltaic cells 12, which are located essentially at the focal plane of Fresnel lenses 11. A secondary optical element (such as an homogenizer or a secondary concentrator), which is not shown, can be placed on top of the cell. Many rays hitting the lenses from the rest of the sky (region sky R_{L}) such as the rays inside pencil 16, will reach the focal plane, striking auxiliary PV cells 13. More slanting rays, such as those in pencil 17, strike mirrored sidewall 14, which reflects them onto cells 12, 13. A person skilled in the art will understand how to interconnect the two types of cells electrically so as to minimize any mismatch losses.

Note that the auxiliary PV cells 13 will not be as hot as the main cells 12, because the irradiance they receive is low. This is of special interest if their temperature coefficient of efficiency decline is high, as occurs in silicon cells. They will thus operate cooler than in a typical one-sun installation, so much so that they could serve as heat spreaders for the main cells 12. In the embodiment of FIG. 1, 3-5% of the DNI light rays impinge on the vertical facets or rounded facet tips of the Fresnel lens, and are mis-deflected away from main cells 12. Those rays would typically be lost in a conventional CPV system. In the present embodiment, much of this light will be collected on secondary cells 13, benefiting the energy collection. Fresnel lenses typically transmit about 80-85% as much diffuse radiation as a flat window. As long as slanted diffuse rays 17 do not hit sidewalls 14 more than twice, they will keep most of their energy.

FIG. 2 shows a conceptual block diagram of an embodiment of a photovoltaic system. For simplicity these symbolic shapes are shown with square contours and flat surfaces, but the invention is not restricted to literally those shapes, as a person skilled in the art would understand. PV system 20 shown in the block diagram in FIG. 2 can either represent an entire PV system or a unit element of an array. Angle splitting optical device 21 collects the solar radiation impinging at every point on entry aperture 22 within angular region R_{H}, shown as solid angle 24, and angular region R_{L}, shown as solid angle 26 (with a central void corresponding to solid angle 24), in such a way that rays within the smaller solid angle 24 are directed to primary photovoltaic receiver 23, while rays within the larger solid angle 26 are directed to larger, lower-cost secondary photovoltaic receiver 24. In the embodiment of FIG. 1, the actual angle splitting is done by the relative positioning of small primary photovoltaic cell 12 and Fresnel lens 11.

The primary photovoltaic receiver 23 is typically optimized to convert concentrated direct-beam solar radiation, and the secondary photovoltaic receiver 24 is typically optimized to convert unconcentrated diffuse radiation. The feasibility of the system derives from the positive marginal utility of the extra low-cost cells collecting relatively weak flux surrounding the focal zone of concentration. If their capital installation cost per extra annual kW-hour they generate is less than or equal to that of the main HCPV system, then their addition is economically justified, particularly when they add nothing to operating costs. Even if the incremental capital installation cost per extra annual kW-hour of the secondary cells is slightly higher, their addition may still be economically justified, depending on what alternatives are available. For example, if land for a larger HCPV array is not available, or is only available at higher cost, the marginal value of the secondary cells may be compared with more expensive alternative sources of additional power.

This configuration is particularly applicable to CPV systems that track the sun in two axes, keeping the sun disk Rₛᵤₙ in an essentially fixed direction relative to the CPV cells and the optics of the concentrator. In this case, the angular region R_{H} must enclose the sun disk region Rₛᵤₙ, having angular radius αₛᵤₙ≈0.265 deg, so:

Rₛᵤₙ [symbol] R_{H}

and therefore Ω_{H}≧Ωₛᵤₙ≈π sin²(0.265 deg)=67 μsteradians. Region R_{H} is preferably round and significantly bigger than Rₛᵤₙ to allow for tolerances. The angular radius of the largest circle R_{α} that is entirely inside R_{H} and concentric with Rₛᵤₙ is usually considered the acceptance angle of the system, α. Since R_{H} may vary in practice from point to point on the concentrator's entry aperture, α is usually defined formally, such that the optical efficiency for all directions inside R_{α} is not lower than a fixed proportion, e.g., 90%, of the maximum optical efficiency inside R_{α}. In practice, this angle can range from 0.5° to 2°. In general, the regions R_{H} and R_{L} are not necessarily adjacent to each other, neither must they be connected sets.

The entry aperture 22 can be a real surface (such as the front surface of a flat glass or acrylic plate), or a virtual surface (such as the projection onto an imaginary plane of the surface of a mirror). The entry aperture 22 can also be such that the set of rays that impinge on it do not all originate inside any hemispherical solid angle, so that solid angle Ω_{L} can be greater than 2π, opening the possibility of collecting even albedo radiation (which can be significant in the PV system if it is mounted on a whitened ground or roof). As an example, surface 22 can be the front and side surfaces of an essentially transparent box, and photovoltaic receiver 24 can be made of bifacial solar cells, so that nearly all of region R_{L} (4π steradian) illuminates receiver 24. The photovoltaic receivers 23 and 24 can comprise a single solar cell or a set of several solar cells, electrically arrayed in series or parallel connection.

This arrangement can produce an annual electrical energy density (in kWh/(m²·year)) higher than the prior art. The reason for this is the maximum conversion efficiency (over 40% at present) today is by III-V triple-junction cells operating under concentration (in the 100 to 600 suns range). Using them economically requires that solid angle Ω_{H} dedicated to receiver 23 be relatively small, bounded and limited to only direct normal radiation. Where R_{H} is a circle of radius α, the thermodynamic limit of concentration-acceptance angle decrees that α<sin⁻¹(n/√C_{g,H}), where n is the refractive index of the encapsulant material surrounding the solar cell, typically n=1.4-1.5).

To collect the remainder of the available irradiation (or most of it) striking the entry aperture (up to Ω_{L}=4π steradians is conceivable), the same thermodynamic limit applies (for instance, for a mono-facial flat entry aperture 13, if the entire hemisphere is to be collected, the concentration is limited to C_{g,L}<n² for monofacial solar cells and C_{g,L}<2n² for bifacial solar cells). Even these can only be obtained by a trapezoidal rod, economical only for the small focal-spot cells of HCPV systems.

The maximum annual electrical energy density of the system would be produced if the same III-V triple-junction cells (optimized for no or low concentration) are also used as receiver 24, and probably they could be close to 30% efficient. However, this is not practical for cost competitive electricity generation, although it may be applicable for niche applications in which only the energy density and not the cost is a consideration. On the other hand, lower cost silicon cells can be used to provide additional electricity at a lower efficiency and cost.

To quantify the potential gain in energy generation and cost effects, consider three technologies for two-axis tracking systems:

FPV=1-sun flat PV modules using silicon cells that face the sun all day
HCPV=High concentration PV modules using III-V cells only
ACPV=assisted high-concentration PV, using the same two types of cell technology as FPV and HCPV, the latter collecting direct radiation and the former the global minus direct radiation. For such a comparison, one “merit function” R is the capital cost of annual electrical energy delivered.

$$R = \frac{system cost ( \$ )}{annual nominal generated electrical energy ( kWh )} \qquad ( 1 )$$

Note that because R is expressed as cost per unit of power, low values of R are more meritorious.

After dividing both numerator and denominator by the total area of the respective concentrator apertures, the merit functions and energy outputs of the respective systems are

$${R}_{FPV} = \frac{{C}_{0} + {C}_{L}}{{E}_{FPV}} + {C}_{non - cell}$$

$${E}_{FPV} = GNI * {η}_{L}$$

$${R}_{CPV} = \frac{{C}_{0} + {C}_{H}}{{E}_{CPV}} + {C}_{non - cell}$$

$${E}_{CPV} = DNI * {η}_{H} {η}_{opt , H}$$

$${R}_{ACPV} = \frac{{C}_{0} + {C}_{H} + {C}_{L}}{{E}_{AHFV}} + {C}_{non - cell}$$

$${E}_{ACPV} = DNI * {η}_{H} {η}_{opt , H} + ( GNI - DNI ) {η}_{L} {η}_{opt , L}$$

Using the numerical values discussed above and listed below, E_{FPV}=516 kWh/(m²·year), E_{CPV}=603 kWh/(m²·year) and E_{ACPV}=694.5 kWh/(m²·year).

Since C_{non-cell} is common, it can be, and is, set to 0 just for comparison purposes. With that simplification, in this case, the ACPV system outperforms the CPV system and the flat panel, with E_{CPV}/E_{FPV}=1.17, E_{ACPV}/E_{FPV}=1.35 and E_{ACPV}/E_{CPV}=1.15. The addition of auxiliary cells to the concentrator results in 15% more electricity generated per dollar. Including a realistic value for C_{non-cell} will reduce the ratios somewhat, but will not change their substance.

The symbols are:

| Symbol | Unit | Description |
|---|---|---|
| C_{H} | $/m² | costs specific to the use of HCPV III-V high efficiency cells. For |
| | | instance, III-V cells, heat sink, incremental costs to tracker for |
| | | higher accuracy, etc. |
| C_{L} | $/m² | costs specific to the use of 1-sun flat PV cells |
| C₀ | $/m² | Costs, common to the three technologies, that are proportional to |
| | | system entry aperture area (the module cover, frame, tracker, the |
| | | structural supporting beams, land use and preparation, etc.) |
| C_{non-cell} | ($/kWh)/year | Costs, common to the three technologies, that are proportional to |
| | | the system power (as the inverter, etc). |
| E | kWh/(m² · year) | Nominal annual DC electrical energy density (kWh/(m² · year)) |
| η_{L} | dimensionless | Efficiency of one-sun cells (20%) |
| η_{H} | dimensionless | Efficiency of HCPV cells (40%) |
| η_{opt, H} | dimensionless | Optical throughput of concentrator (75%) |
| η_{opt, L} | dimensionless | Concentrator throughput of diffuse rays (70%) |
| GNI | kWh/(m² · yr) | Global radiation at normal incidence (2580) |
| DNI | kWh/(m² · yr) | Direct normal irradiation (2012) |

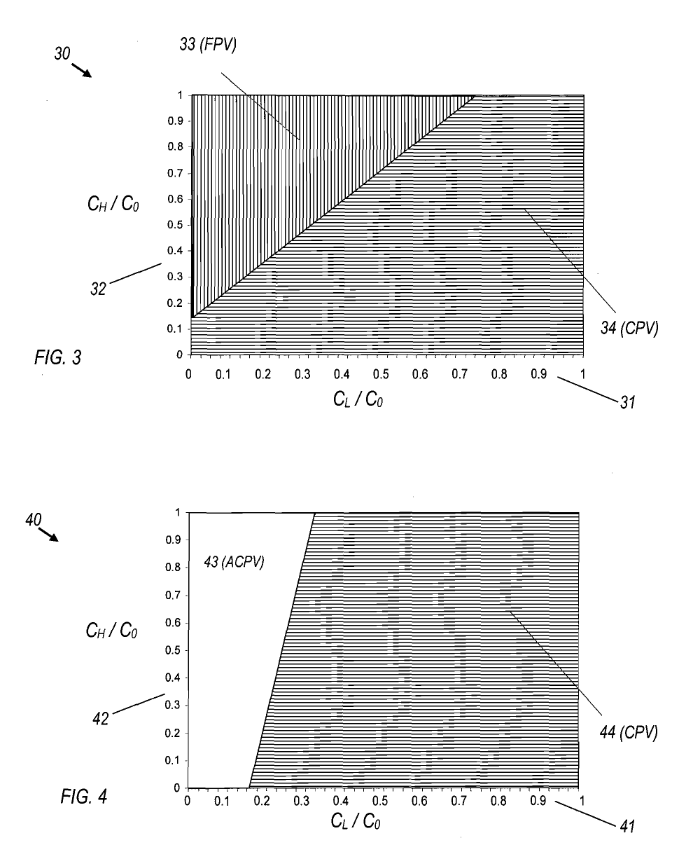

In the near future, it is expected that the learning curve of module manufacturing will decrease the numerator in merit function R much faster than the expected increase in efficiencies. So for the purpose of projecting the potential relative performance of the three systems as the cost comes down, the denominator can be considered constant. Therefore, it is interesting to evaluate the merit function R as a function of the three cost terms C_{L}, C_{H} and C₀. The two ratios of their values can be used to display the minimum values of the merit function R. FIGS. 3, 4, and 5 show the plane C_{L}/C₀−C_{H}/C₀ for the case in which E_{CPV}/E_{FPV}=1.17 and E_{ACPV}/E_{FPV}=1.35 (and thus E_{ACPV}/E_{CPV}=1.15). Several regions are highlighted.

FIG. 3 shows graph 30 comprising horizontal axis 31 for the ratio C_{L}/C₀ of one-cell cost to common per-area costs, and vertical axis 32 for the ratio C_{H}/C₀ of concentrator cost to common per-area costs. FIG. 3 particularly shows the case in which E_{CPV}/E_{FPV}=1.17. Within top-left region 33 FPV has lower R values than CPV, while within bottom-right region 34 CPV has the lower R value. This illustrates that the CPV technology will have difficulty competing with FPV if the cost of efficient 1-sun flat PV cells (C_{L}) is sufficiently low compared to C₀.

FIG. 4 shows the comparison between CPV and ACPV for the case in which E_{ACPV}/E_{CPV}=1.15. Within left region 43 ACPV technology has lower values of R than CPV, while in right region 44 CPV has projected lower R values than ACPV. This illustrates that ACPV will be superior to CPV if the costs of 1-sun flat PV cells (C_{L}) is sufficiently low compared to C₀, exactly where concentrators alone are vulnerable.

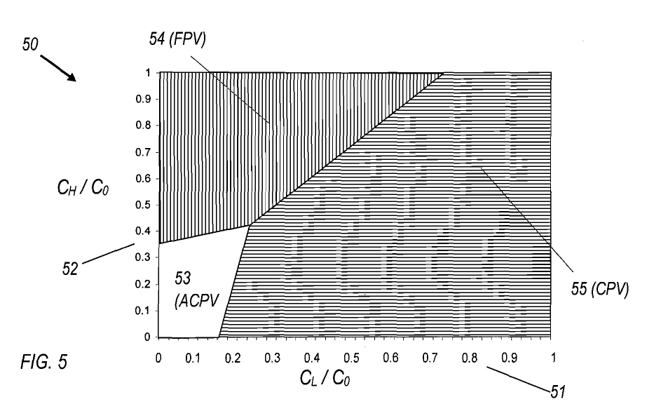

Finally, FIG. 5 shows the comparison of the three technologies, FPV, CPV and ACPV together. In regions 53, 54 and 55, technologies ACPV, CPV and FPV will respectively have the minimum R. This illustrates that the ACPV technology will lead to lower R values than the FPV technology, and the lowest R values of the three technologies, when common costs C₀ are dominant, which is to be expected as cell technology continues to progress.

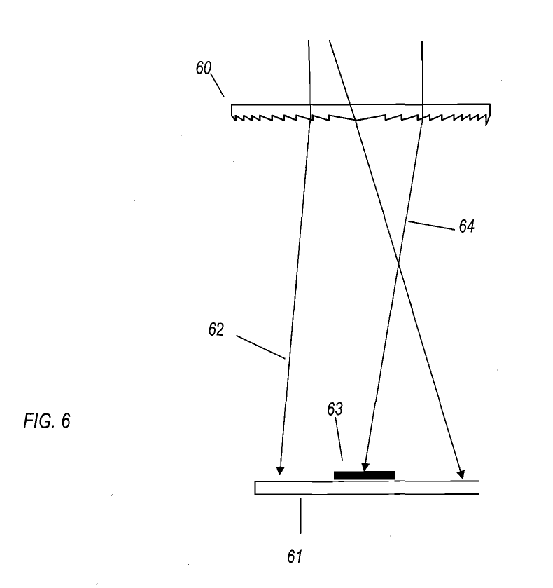

FIG. 6 shows that the sky-splitting device may be a Fresnel lens 60 in which the DNI radiation 64 impinging on the active facets of the Fresnel lens is concentrated onto the high-efficiency concentrator solar cell 63, while the DNI radiation 62 impinging on the vertical facets or facets corners and the diffuse radiation passing through the lens are collected by lower efficiency solar cells surrounding the high efficiency ones.

The III-V or other high concentration cell 63 may be mounted on a bigger low concentration solar cell 61, and the low concentration cell may then act as a heat spreader for heat from the high concentration cell.

The high concentration cell may be transparent to light of one part of the solar spectrum. For example, double-junction solar cells are available in which the substrate has been removed, and which are transparent to the infrared above 900 nm approx. The transmitted light to which the high concentration cell is transparent may then be absorbed and converted by the low-concentration cell behind.

Although specific embodiments have been described, the person skilled in the art will understand how features of different embodiments may be combined, and how various features may be modified, added, or omitted, without departing from the scope and spirit of the invention as defined in the claims.

For example, in one of the preferred embodiments the sky is divided such that the DNI radiation is concentrated on high efficiency solar cells, which may be III-V triple junction or other tandem solar cells, while at least part of the diffuse and/or albedo radiation is directed towards essentially 1-sun solar cells, which may be monofacial or bifacially active. Bifacial cells, which can accept diffuse radiation from the sky through a front face and radiation reflected from the ground through a rear face, may be more efficient but, because of the need to mount them with both the front and the rear faces exposed, less easy to install.

In another embodiment, the diffuse radiation is also concentrated on high efficiency solar cells, which may be the same type as or a different type from the cells collecting the DNI radiation. The series resistance of each set of cells may then be optimized for the irradiance or concentration level it receives.

The two cell designs may be made on the same semiconductor substrate, with separate electrical connections.

One or both cell types may be back-contacted cells (as Sunpower's).

The sky-splitting optics that directs the direct and diffuse radiation to the two sets of cells may be a microlens array.

With some cell types, for example, where a high-concentration triple junction cell with a germanium bottom junction is combined with a silicon cell for the diffuse radiation, the spectrum-splitting approach described in U.S. Provisional Patent Application No. 61/214,548 titled “Four-Junction Two-Terminal Photovoltaic Device,” filed 24 Apr. 2009 by Benítez et al. may be used. Part of the GNI radiation in the spectral range usually collected by the germanium junction, (which is usually wasted because of a mismatch between the three junctions of a conventional triple junction cell) is sent towards the 1-sun silicon cell, reducing the heat load of the triple junction cell as well as improving efficiency. That can be done, for instance using a GBO mirror optic.

In one practical embodiment, the DNI radiation is concentrated on M×N_{H} high-efficiency solar cells that will produce a certain voltage V_{H} per cell, and the diffuse radiation is directed onto M×N_{L} 1-sun solar cells that will produce a certain voltage V_{L} per cell, where M is a positive integer and N_{H} and N_{L} are the minimum positive integers such that N_{H}×V_{H}≈N_{L}×V_{L}≈V_{Row}. Thus, the high-efficiency solar cells can be connected in series in a row of N_{H} cells and the 1-sun solar cells can be also connected in series in a row of N_{L} cells. These rows then all generate approximately the same voltage V_{Row}, and can be paralleled. The multiplier M allows rows to be connected either in series to multiply the voltage V_{Row}, and/or in parallel to multiply the current. As an example, using triple junction solar cells (for which V_{H}≈3 V) and crystalline silicon cells (for which V_{L}≈0.6 V), M=6, N_{H}=1 and N_{L}=6 can be used to make an 18V module.

We claim:

1. A solar photovoltaic system comprising:
a tracking concentrator;
a primary photovoltaic cell upon which direct normal radiation is concentrated by the concentrator; and
one or more auxiliary photovoltaic cells surrounding said primary cell and receiving solar radiation from said concentrator that misses said primary cell.

2. The system of claim 1 wherein said concentrator comprises a Fresnel lens.

3. The system of claim 2 also comprising reflective sidewalls that deflect greatly slanted solar radiation from said Fresnel lens toward said secondary cells.

4. A photovoltaic system comprising:
a concentrator;
a primary photovoltaic cell upon which direct normal radiation is concentrated by the concentrator; and
a secondary photovoltaic cell receiving radiation from the concentrator that misses the primary cell.

5. The photovoltaic system according to claim 4, further comprising a tracker to direct the concentrator and primary photovoltaic cell to receive said normal radiation from a selected external source.

6. The photovoltaic system according to claim 5, which is suitable for use as a solar photovoltaic generating system, and wherein the tracker is a two-axis tracker operable to track the apparent movement of the sun relative to the earth's surface, and wherein the concentrator is operative to concentrate direct sunlight on said primary photovoltaic cell, and to direct at least some diffuse skylight onto said secondary photovoltaic cell.

7. The photovoltaic system according to claim 4, wherein said secondary photovoltaic cell comprises a plurality of secondary photovoltaic cells surrounding said primary photovoltaic cell.

8. The photovoltaic system according to claim 4, wherein said secondary photovoltaic cell is a bifacial cell exposed on its rear face to light entering the system from the hemisphere opposite the entry aperture of the concentrator.

9. The photovoltaic system of claim 4, wherein said concentrator is a Fresnel lens.

10. The photovoltaic system of claim 4, further comprising reflective sidewalls that deflect greatly slanted incident radiation from said Fresnel lens toward said cells.

11. The photovoltaic system of claim 4, further comprising an array of said primary photovoltaic cells, and a corresponding array of said concentrators each positioned to concentrate direct normal irradiance onto a corresponding one of said array of primary photovoltaic cells.

12. The photovoltaic system of claim 4, further comprising an array of said secondary photovoltaic cells between and around said primary photovoltaic cells of said array.

13. A method of generating solar power, comprising:
providing a concentrator;
providing a primary photovoltaic cell;
tracking the concentrator such that it concentrates direct solar radiation onto the primary photovoltaic cell; and
providing a secondary photovoltaic cell receiving from the concentrator sky radiation that misses the primary cell; and
using the primary and secondary photovoltaic cells to convert energy in said direct solar radiation and sky radiation into electricity.

14. The method according to claim 13, further comprising combining the electrical outputs of the primary and secondary photovoltaic cells.

15. The photovoltaic system according to claim 13, further comprising using a two-axis tracker to track the apparent movement of the sun relative to the earth's surface, and to direct the concentrator and primary photovoltaic cell to receive said direct radiation from the sun.
